(19) United States
(12) Patent Application Publication
(10) Pub. No.: US 2002/0063937 A1
(43) Pub. Date: May 30, 2002

(54) Optical receiving apparatus

(76) Inventor: Osamu Kikuchi, Saitama (JP)

Correspondence Address: VOLENTINE FRANCOS, PLLC, Suite 150, 12200 Sunrise Vally Drive, Reston, VA, 20191, US

(21) Appl. No.: 09/992,000

(22) Filed: Nov. 26, 2001

(30) Foreign Application Priority Data
Nov. 29, 2000 (JP) 362527/2000

(51) Int. Cl. H04B 10/06; H03F 3/08

(52) U.S. Cl. 359/189; 330/308

(57) ABSTRACT

A pre-amplifier outputs amplified signals in response to an input optical signal, and a data detection circuit outputs a data detection signal in response to a change in a logic value of at least one of the amplified signals. A reset circuit outputs a reset signal in response to a change in a logic value of the data detection signal, and a threshold control circuit is responsive to the reset signal to remove a bias voltage which is present in at least one of the amplified signals.

### BACKGROUND OF THE INVENTION

1. Field of the invention

The present invention relates to an optical receiving apparatus, and more particularly, to an optical receiving apparatus which may be used to receive a biased optical burst signal.

The present application claims priority under 35 U.S.C. §119 to Japanese Patent Application No. 2000-362527, filed Nov. 29, 2000, which is herein incorporated by reference in its entirely for all purposes.

2. Description of the related art

In a conventional optical receiving apparatus, an optical input signal is converted into an electric current signal by a light receiving element such as photo-diode, and the electric current signal is amplified by a preamplifier. A reference level of the amplified electric current signal is determined by an auto-threshold control (ATC) circuit, and the electric current signal is further amplified by a limit-amplifier according to the reference level of the amplified electric current signal.

The ATC circuit basically works the same as an auto-offset compensation (AOC) circuit and an auto-bias control (ABC) circuit in that it detects top and bottom peak levels of the amplified electric current signal and determines the best reference level therefrom.

FIG. 1 is a block diagram showing the construction of the aforementioned conventional optical receiving apparatus.

A light receiving element 1 such as a photo-diode receives an optical burst signal OPT and converts the same into an electric current signal. A pre-amplifier 2 amplifies the electric current signal and outputs a non-inverting phase signal D and an inverting phase signal ND. An auto-threshold control (ATC) circuit 4 detects top and bottom peak values of the amplified electric current signal and determines a reference voltage level in accordance with the peaks values. A comparator 5 discriminates with reference to the reference voltage level, and outputs the output signal DOUT according to the reference level of the amplified electric current signal. The ATC circuit 4 and the comparator 5 together constitute a main amplifier of the optical receiving apparatus.

The ATC circuit 4 is constructed with first and second peak hold circuits 21, 22, first and second adders 23, 24, and a differential amplifier 25. The first peak hold circuit 21 detects a peak value of the non-inverting phase signal D and outputs an output signal PKP which is the same as the peak value of the signal D. The second peak hold circuit 22 detects a peak value of the inverting phase signal ND and outputs an output signal PKN which is the same as the peak value of the signal ND. The first adder 23 adds the inverting phase signal ND and the output signal PKP of the first peak hold circuit 21. The second adder 24 adds the non-inverting phase signal D and the output signal PKN of the second peak hold circuit 22. The differential amplifier 25 amplifies a difference between an output signal NQ of the first adder 23 and an output signal Q of the second adder 24 to desired levels, and then outputs an amplified signal. The combination of the first and second peak hold circuits 21, 22 and the differential amplifier 25 each may be similarly constructed in single or multiple stages.

Such a conventional optical receiving apparatus is disclosed in the magazine article of The Syntactic Congress of The Institute of Electronics, Information and Communication Engineers B-10-128, pp. 637, “156 Mbps Optical Receiver for Burst Mode Signal”, published in 1997, and in Japanese Laid-Open Patent Publication: HEI08-084160, published on Mar. 26, 1996.

FIGS. 2(a) through 2(g) shows signal waveforms at various portions of conventional optical receiving apparatus shown in FIG. 1, in the case where the optical signal input to the optical receiving apparatus includes a bias voltage. FIG. 2(a) shows a signal waveform of the optical signal OPT at the light receiving element 1. FIG. 2(b) shows signal waveforms of the non-inverting phase signal D and the inverting phase signal ND at the preamplifier 2. FIG. 2(c) shows signal waveforms of the non-inverting phase output signal PKP of the first peak hold circuit 21 and the inverting phase output signal PKN of the second peak hold circuit 22. FIG. 2(d) and FIG. 2(f) show different signal waveforms of the output signal NO of the first adder 23 and the output signal Q of the second adder 24. FIG. 2(e) and FIG. 2(g) show different signal waveforms of the output signal DOUT of the comparator 5.

FIG. 2(d) shows that an overlap range of the output signal NQ and the output signal Q is decreased as the bias voltage is increased. As a result, in FIG. 2(e), a pulse width of a logical value ‘0’ of the output signal DOUT is decreased.

FIG. 2(f) shows that the output signal NQ and the output signal Q are not overlapped at all when the bias voltage is further increased. In this case, as shown in FIG. 2(g), a logical value ‘1’ of the output signal DOUT is fixed and optical signals can not be accurately received.

It is also known that the larger the influence of an optical quenching ratio resulting from the signal waveform of the non-inverting phase signal D and the inverting phase signal ND, the more the output signal DOUT will inhibit the logical value ‘1’. Therefore, when there is a large optical quenching ratio, the pulse width of the logical value ‘0’ decreases in a manner similar to that shown in FIG. 2(e).

FIG. 9 is a diagram for explaining the gain saturation of the preamplifier 2. In the case of an optical burst signal, the bias voltage is subjected to a linear gain, whereas the bias voltage is within the saturated region of the preamplifier. Consequently, the conventional optical receiving apparatus holds the offset error in the form of the burst.

Another conventional optical receiving apparatus includes selectors which switch between many types of feedback resistance. The saturation region of the preamplifier is not used to thereby prevent the duty factor variation of the optical signal and enlarge a receiving dynamic range of the optical signal input to the optical receiving signal.

Such a conventional optical receiving apparatus is disclosed in the magazine article of the Syntactic Congress of the Institute of Electronics, Information and Communication Engineers SC-12-3, pp. 239, “156 Mb/s 3.3 V Burst Optical Receiver LSI for FSAN”, published in 1999, and also in the magazine article of the 1997 8^{th} International Workshop on Optical/Hybrid Access Networks Conference Proceedings Poster Session, pp. 12-18, “A 156 Mb/s CMOS Optical Receiver ICs for Burst-mode transmission”, published on Mar. 2-5, 1997.

However, there is a problem inherent in the conventional optical receiving apparatus. Input terminals of the conventional optical receiving apparatus create extra capacitance which in turn adds many types of feedback resistance. A frequency characteristic and a noise characteristic of the preamplifier is thereby degraded. As a result, an operational speed and a sensitivity of the optical receiving apparatus are degraded, and a receiving dynamic range is reduced.

### SUMMARY OF THE INVENTION

It is therefore an objective of the invention to provide an optical receiving apparatus which can accurately receive an optical input signal having a large bias voltage.

To achieve this object, an optical receiving apparatus includes a data detection circuit which detects an optical signal input to the optical receiving apparatus and outputs a data detection signal in response to a change in a logic value of at least one of the amplified signals supplied from a pre-amplifier, a reset circuit which generates a reset signal in response to a change in a logic value of the data detection signal, and a threshold control circuit which is responsive to the reset signal to remove a bias voltage which is present in at least one of the amplified signals.

According to the present invention, since the degradation of the output signal of the comparator can be controlled or inhibited, the optical receiving apparatus of the present invention can accurately to receive an optical signal, even if the optical signal has a large bias voltage. Moreover, the narrowing of the receiving dynamic range, the degradation of the operational speed due to the degradation of duty factor of the optical receiving apparatus and the degradation of the sensitivity of the apparatus due to increase the bit error can be inhibited.

The above and further objects and novel features of the invention will become more fully apparent from the following detailed description, appended claims and accompanying drawings herein.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a block diagram showing a conventional optical receiving apparatus;

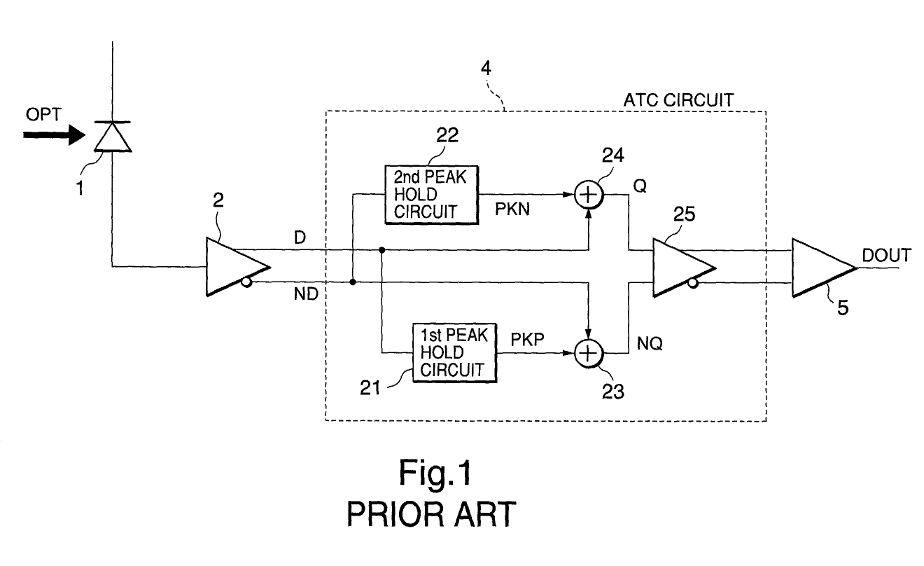

FIGS. 2(a) through 2(g) shows signal waveforms at various portions of the conventional optical receiving apparatus shown in FIG. 1;

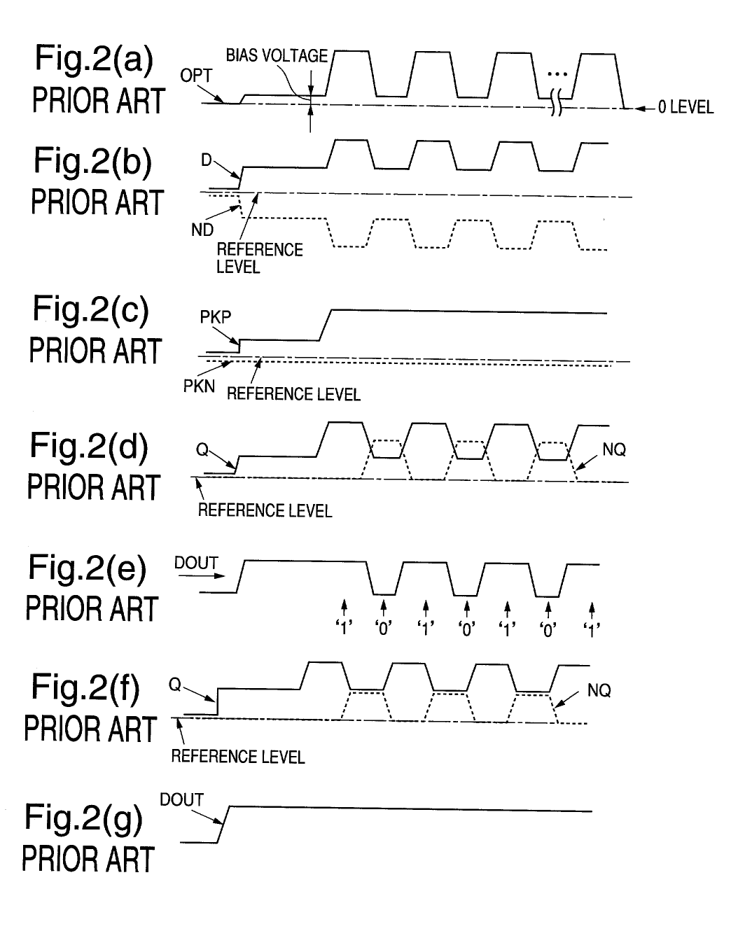

FIG. 3 is a block diagram showing an optical receiving apparatus according to a first preferred embodiment of the present invention;

FIGS. 4(a) through 4(g) shows signal waveforms at various portions of the optical receiving apparatus according to the first preferred embodiment of the present invention shown in FIG. 3;

FIG. 5 is a block diagram showing an optical receiving apparatus according to a second preferred embodiment of the present invention;

FIGS. 6(a) through 6(d) shows signal waveforms at various portions of the optical receiving apparatus according to the second preferred embodiment of the present invention shown in FIG. 5;

FIG. 7 is a block diagram showing an optical receiving apparatus according to a third preferred embodiment of the present invention;

FIGS. 8(a) through 8(d) shows signal waveforms at various portions of the optical receiving apparatus according to the third preferred embodiment of the present invention shown in FIG. 7; and

FIG. 9 is a diagram for explaining the gain saturation of a preamplifier.

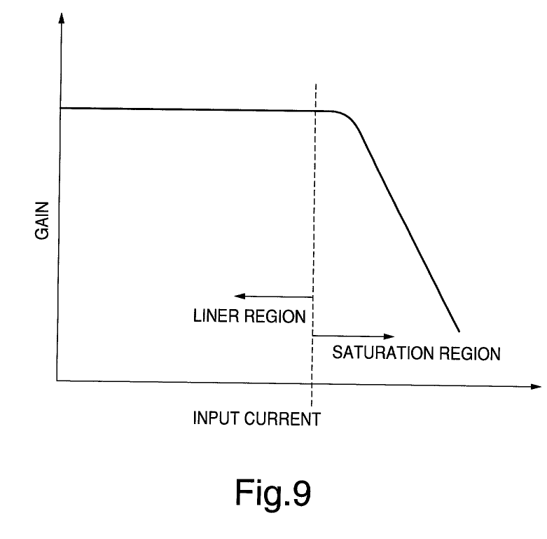

### DETAILED DESCRIPTION OF THE PREFERRED EMBODIMENTS

Preferred embodiments of the present invention will hereinafter be described in detail with reference to the accompanying drawings. The drawings used for this description typically illustrate major characteristic parts to facilitate understanding of the invention.

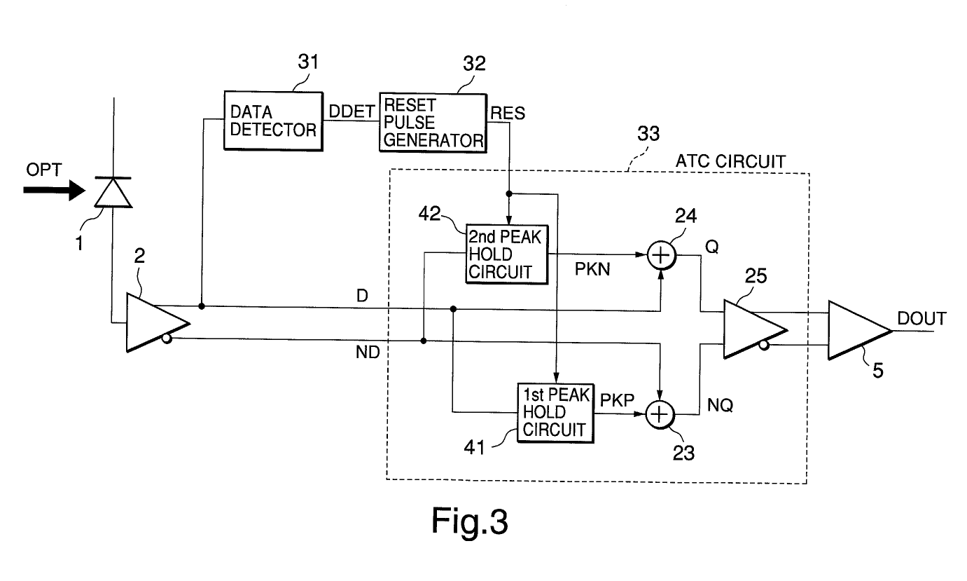

FIG. 3 is a block diagram of an optical receiving apparatus according to a first preferred embodiment of the present invention. As shown, the apparatus includes a light receiving element 1, a pre-amplifier 2, a data detector 31, a reset pulse generator 32, an auto-threshold control (ATC) circuit 33 and a limit-amplifier 5. The ATC circuit 33 is constructed with first and second peak hold circuits 41, 42, first and second adders 23, 24 and a differential amplifier 25.

The data detector 31 detects an optical signal in accordance with a rising edge of a non-inverting phase signal D which is outputted from the pre-amplifier 2, and outputs a data detect signal DDET which has a non-inverting phase. In other words, the data detector 31 detects the optical signal input to the optical receiving apparatus, in accordance with a change in the logical value of the non-inverting phase signal D.

The reset pulse generator 32 generates a reset pulse in accordance with the data detect signal DDET and outputs the same to the peak hold circuits 41, 42. In particular, the reset pulse is a peak reset pulse RES which has a predetermined pulse width, and is generated in response to a rising edge of the data detect signal DDET.

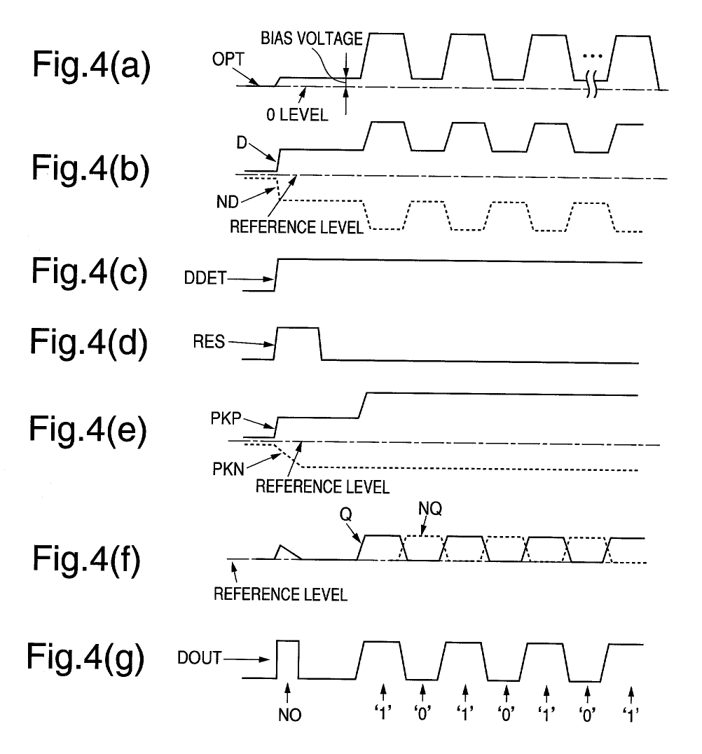

FIGS. 4(a) through 4(g) shows signal waveforms at various portions of the optical receiving apparatus shown in FIG. 3, in the case where the optical signal input to the optical receiving apparatus includes a bias voltage. FIG. 4(a) shows a signal waveform of the optical signal OPT in the form of burst at the light receiving element 1, and FIG. 4(b) shows signal waveforms of the non-inverting phase signal D and the inverting phase signal ND at the pre-amplifier 2.

FIG. 4(c) shows a signal waveform of the data detect signal DDET at the data detector 31. FIG. 4(d) shows a signal waveform of the peak reset pulse RES which has the predetermined pulse width, at the reset pulse generator 32. The predetermined pulse width of the reset pulse RES is defined by a given period which is equal to or more than an amount of time needed by the second peak hold circuit 42 to remove the constituent part of the bias voltage of the optical signal from the inverting phase signal ND. As a result, the constituent part of the bias voltage of the optical signal is completely removed.

As shown in FIG. 4(e), when the peak reset pulse RES is input into the second peak hold circuit 42, a voltage level of the output signal PKN gradually falls (discharges) until that of the inverting phase signal ND due to the discharging during the predetermined pulse width of the peak reset pulse RES. On the other hand, the output signal PKP is peak-held at the voltage level which includes the bias voltage, because a non-inverting phase bias voltage level is maintained while the peak reset pulse RES is input into the first peak hold circuit 41, since both the output signal PKP and the reset pulse RES are the non-inverting phase.

FIG. 4(f) shows both signal waveforms of the output signal NQ of the first adder 23 and the output signal Q of the second adder 24. The bottom level of the output signal NQ corresponds to a reference voltage level of the same because the bias voltage would be canceled due to addition of the inverting phase signal ND and the output signal PKP at the first adder 23. Equally, the bottom level of the output signal Q corresponds to the reference voltage level of the same because the bias voltage would be canceled due to addition of the non-inverting phase signal D and the output signal PKN at the second adder 24. As a result, the top level of the output signal NQ and the bottom of the output signal N, and the bottom level of the output signal NQ and the top of the output signal N, have the same potential (the same voltage level) and opposite phases, respectively.

Consequently, at the output signal DOUT of the comparator 5, the pulse widths of the logical values ‘0’ and ‘1’ would be the same as shown in FIG. 4 (g). The degradation of the output signal DOUT is avoided.

According to the first preferred embodiment of the present invention, since the first and second peak hold circuits 41, 42 output the output signals PKN and PKP in accordance with the peak reset pulse RES which has the predetermined pulse width, the degradation of the output signal DOUT can be controlled or inhibited. Therefore, the optical receiving apparatus of the first preferred embodiment can be accurately receive an optical signal even if the optical signal has a large bias potential.

A non-canceled constituent part of the bias voltage remains while the first period of the peak reset pulse RES is input to the second peak hold circuit 42. This is because the output signal PKN is gradually peak-held at the bias voltage level. This constituent part of noise NO for the output signal DOUT is shown in FIG. 4(g). However, since the constituent part of the noise NO arises along with the data detect signal DDET and the peak reset pulse RES, for example, the noise NO can be removed by using a self-refresh signal which is generated in accordance with the peak reset pulse RES.

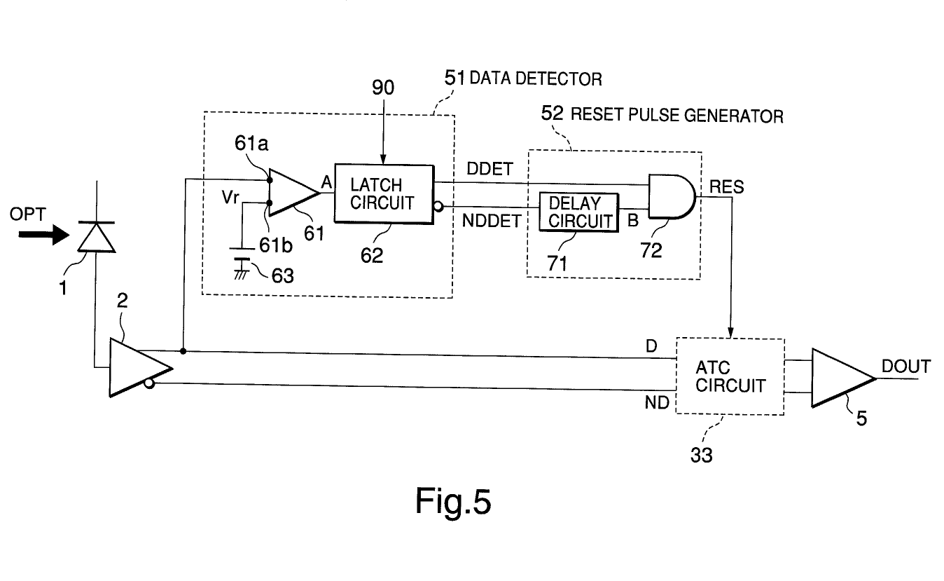

FIG. 5 is a block diagram of an optical receiving apparatus according to a second preferred embodiment of the present invention. In particular, the second preferred embodiment is different from the first preferred embodiment with respect to a data detector 51 and a reset pulse generator 52. The data detector 51 detects the optical signal in accordance with the non-inverting phase signal D and outputs the data detect signal DDET. In addition, the data detector 51 detects the optical signal in accordance with a falling edge of an inverting phase signal ND which is one of the outputs of the pre-amplifier 2, and outputs a data detect signal NDDET which has an inverting phase. The reset pulse generator 52 generates a reset pulse in accordance with both the data detect signal DDET and the data detect signal NDDET, and outputs the same to the peak hold circuits 41, 42 (FIG. 3).

The data detector 51 is constructed with a comparator 61, a latch circuit 62 such as SR-flip-flop and a fixed voltage supply 63. The fixed voltage supply 63 generates a fixed voltage Vr. The voltage level of the fixed voltage Vr is higher than the reference voltage level of the non-inverting phase signal D. The comparator 61 has a non-inversion input terminal 61a which inputs the non-inverting phase signal D and an inversion input terminal 61b which inputs the fixed voltage Vr. The comparator 61 which compares the non-inverting phase signal D with the fixed voltage Vr, and outputs an output signal A. The latch circuit 62 latches the output signal A into its and then outputs the data detect signals DDET, NDDET until a reset signal 90 is input thereto.

The reset pulse generator 52 is constructed with a delay element 71 and an AND circuit 72. The delay element 71 delays the data detect signal NDDET during a given period which is equal to or more than an amount of time needed by the second peak hold circuit 42 to remove the constituent part of the bias voltage from the inverting phase signal ND, and then outputs a delayed signal B. The AND circuit 72 logically multiplies the data detect signal DDET and the delayed signal B, and generates a peak reset pulse RES.

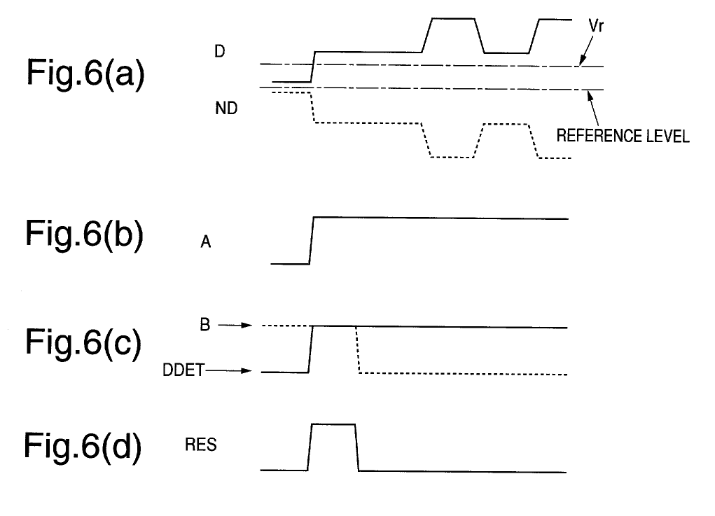

FIGS. 6(a) through 6(d) shows signal waveforms at various portions of the optical receiving apparatus shown in FIG. 5, in the case where the optical signal input to the optical receiving apparatus includes a bias voltage. FIG. 6(a) shows signal waveforms of the non-inverting phase signal D and the inverting phase signal ND, and the fixed voltage Vr. The comparator 61 outputs the output signal A when the non-inverting phase signal D level exceeds the fixed voltage Vr level, as shown in FIG. 6(b).

FIG. 6(c) shows a signal waveform at the AND circuit 72. FIG. 6(d) shows a signal waveform of the reset pulse signal RES. The pulse width of the reset pulse signal RES corresponds to a period which is equal to the data detect signal DDET and the delayed signal B simultaneously being input into the AND circuit 72. In the peak reset pulse RES, the signal waveform of the second preferred embodiment shown in FIG. 6(d) is the same as that of the first preferred embodiment shown in FIG. 4(d). Therefore, a subsequent operation of the second preferred embodiment is the same as that of the first preferred embodiment.

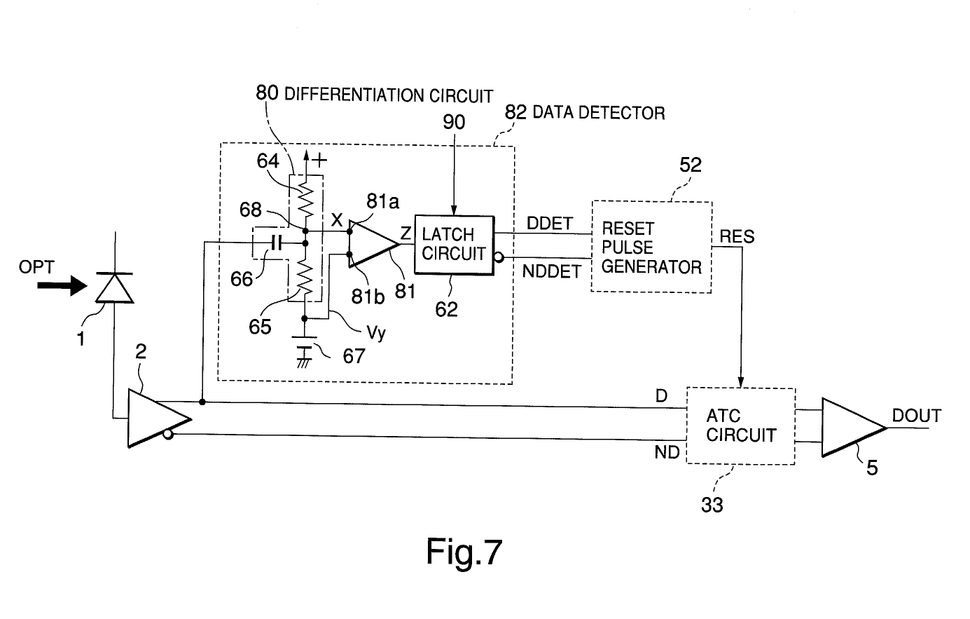

FIG. 7 is a block diagram of an optical receiving apparatus according to a third preferred embodiment of the present invention. In particular, the third preferred embodiment is different from the second preferred embodiment with respect to a data detector 82. The data detector 82 is constructed with the latch circuit 62 such as SR-flip-flop, a fixed voltage supply 67 and a differentiation circuit 80.

The differentiation circuit 80 is designed so that it is possible to generate a differentiated signal X, as the voltage level of a non-inversion input terminal 81b of the comparator 81 is slightly higher than that of an inversion input terminal 81a of the same. The fixed voltage supply 67 generates a fixed voltage Vy. The fixed voltage Vy is properly set in accordance with the bias voltage level input to the comparator 81. The differentiation circuit 80 generates the differentiated signal X in accordance with the inverting phase signal ND.

The comparator 81 has the inversion input terminal 81a which inputs the differentiated signal X and the non-inversion input terminal 81b which inputs the fixed voltage Vy, and outputs an output signal Z when the differentiated signal X level exceeds the fixed voltage Vy level. The latch circuit 62 latches the amplified signal Z and then outputs the data detect signals DDET, NDDET until a reset signal is inputted.

The differentiation circuit 80 is constructed with resistors 64, 65 and a capacitor 66. One terminal of the resistor 64 is connected to a power supply and the other terminal the resistor 64 is connected to one terminal of the resistor 65. The other terminal of the resistor 65 is connected to the fixed voltage supply 67. The capacitor 65 is connected to a node 68 between the resistor 64 and the resistor 65, the node 68 is connected to the inverting input terminal 81a of the comparator 81.

The reset phase generator 52 of the third preferred embodiment is the same as that of the second preferred embodiment.

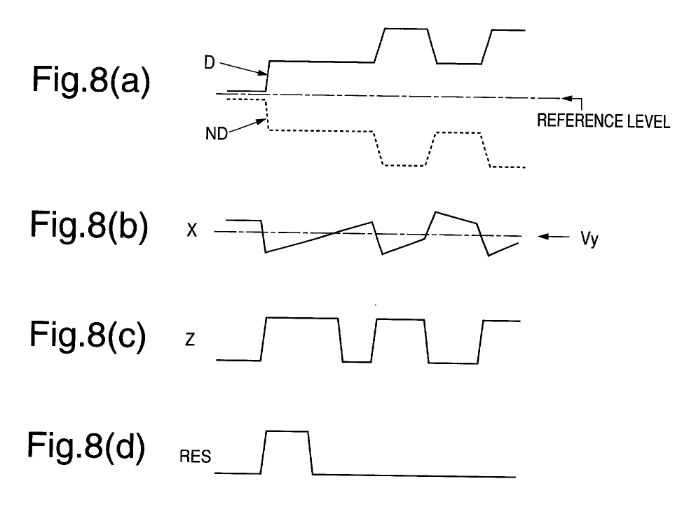

FIGS. 8(a) through 8(d) show signal waveforms at various portions of the optical receiving apparatus shown in FIG. 7, in the case where the optical signal input to the optical receiving apparatus includes a bias voltage. FIG. 8(a) shows signal waveforms of the non-inverting phase signal D and the inverting phase signal ND. In the third preferred embodiment, the differentiation circuit 80 differentiates the inverting phase signal ND and then outputs the differentiated signal X.

FIG. 8(b) is a signal waveform of the differentiated signal X at the node 68. In fast, an initial voltage level of the differentiated signal X is slightly higher than the fixed voltage Vy level. The differentiated signal X level once falls from the initial voltage level of itself and then gradually closes to the initial voltage level again, due to differentiation of the inverting phase signal ND. Thereafter, the differentiated signal X level suddenly changes to under the fixed voltage Vr level, in accordance with the optical signal input to the optical receiving apparatus.

FIG. 8(c) shows a signal waveform of the output signal Z. The comparator 61 outputs the output signal Z while the differentiated signal X level is below the fixed voltage Vr level as shown in FIG. 8(c). A subsequent operation of the third preferred embodiment is the same as that of the second preferred embodiment. Therefore, in the peak reset pulse RES, the signal waveform of the third preferred embodiment shown in FIG. 8(d) is the same as that of the other preferred embodiment mentioned above.

According to the third preferred embodiment, since a detection level of the data detector 81 can be decided by the proper selection of the resistors 64, 65 which are in the differentiation circuit 80, an optimum design of the data detector 81 is facilitated, and the data detection can be stabilized against a change in temperature.

While the preferred embodiments of the present invention presents an example in which the present invention is adopted in the auto-threshold control (ATC) circuit 33, the present invention is not limited to this example and may be adopted in auto-offset compensation (AOC) circuit, the auto-bias control (ABC) circuit and the main amplifier which includes the limit-amplifier 5.

Further, while the first preferred embodiments of the present invention presents an example in which the present invention is used for changing of the logical value of the non-inverting phase signal D, the present invention is not limited to this example and may be used for that of the inverting phase signal ND. Also, while the second and third preferred embodiments of the present invention present an example in which the present invention is used for delaying of the phase of the inverting phase data detect signal NDDET, the present invention is not limited to this example and may be used for that of the inverting phase data detect signal DDET.

As described above, in the optical receiving apparatus according to the present invention, since the degradation of the output signal of the comparator can be controlled or inhibited, the optical receiving apparatus of the present invention can accurately to receive an optical signal, even if the optical signal has a large bias voltage. Moreover, the narrowing of the receiving dynamic range, the degradation of the operational speed due to the degradation of duty factor of the optical receiving apparatus and the degradation of the sensitivity of the apparatus due to increase the bit error can be inhibited. Furthermore, since the present invention facilitates the optimum design of the data detector, the data detection can be stabilized against a change in temperature.

The present invention has been described with reference to illustrative embodiments, however, this description must not be considered to be confined only to the embodiments illustrated. Various modifications and changes of these illustrative embodiments and the other embodiments of the present invention will become apparent to one skilled in the art from reference to the description of the present invention. It is therefore contemplated that the appended claims will cover any such modifications or embodiments as fall within the true scope of the invention.

What is claimed is:

1. An optical receiving apparatus, comprising:
a light receiving element which converts an optical input signal into a corresponding electrical signal;
a pre-amplifier having an input which receives the electrical signal from the light receiving element, a non-inverting output which outputs a first amplified signal, and an inverting output which outputs a second amplified signal which is phase inverted relative to the first amplified signal;
a data detection circuit which receives at least one of the first and second amplified signals from the pre-amplifier, and which outputs a data detection signal in response to a change in a logic value of the at least one of the first and second amplified signals;
a reset circuit which receives the data detection signal from the data detection circuit, and which outputs a reset signal in response to a change in a logic value of the data detection signal; and
a threshold control circuit which detects and outputs first and second peak values of the respective first and second amplified signals output from the pre-amplifier, wherein the threshold control circuit is responsive to the reset signal to remove a bias voltage which is present in at least one of the first and second amplified signals.

2. The optical receiving apparatus according to claim 1, wherein the threshold control circuit comprises:
a first peak hold circuit which outputs a first peak signal corresponding to a peak value of the first amplified signal; and
a second peak hold circuit which outputs a second peak signal corresponding to a peak value of the second amplified signal;
wherein the second peak hold circuit is responsive to the reset signal to remove the bias voltage from the second peak signal.

3. The optical receiving apparatus according to claim 2, wherein the reset signal is a pulse signal having a given period, and wherein the given period of the pulse signal is equal to or more than an amount of time needed by the second peak hold circuit to remove the bias voltage from the second amplified signal.

4. The optical receiving apparatus according to claim 2, wherein the threshold control circuit further comprises:
a first adder which adds the first amplified signal and the second peak signal;
a second adder which adds the second amplified signal and the first peak signal; and
a differential amplifier which differentially amplifies respective outputs from the first and second adders.

5. The optical receiving apparatus according to claim 4, further comprising a comparator which discriminates an output of the differential amplifier with reference to a predetermined reference level, and outputs an output signal.

6. An optical receiving apparatus, comprising:
a light receiving element which converts an optical input signal into a corresponding electrical signal;
a pre-amplifier having an input which receives the electrical signal from the light receiving element, a non-inverting output which outputs a first amplified signal, and an inverting output which outputs a second amplified signal which is phase inverted relative to the first amplified signal;
a data detection circuit having a fixed voltage supply, a first comparator and a latch circuit, wherein the fixed voltage supply supplies a fixed voltage to the first comparator, and wherein the first comparator compares the first amplified signal with the fixed voltage, and wherein the latch circuit latches an output of the first comparator and outputs a first data detection signal and a second data detection signal which is phase inverted relative to the first data detection signal;
a reset circuit which receives the first and second data detection signals from the data detection circuit, and which outputs a reset signal in response to the data detection circuit, wherein the reset circuit includes a delay circuit which delays one of the first and second data detection signals, and a logic circuit which multiplies the other of the first and second data detection signals with an output of the delay circuit to obtain the reset signal;
a threshold control circuit which detects and outputs first and second peak values of the respective first and second amplified signals output from the pre-amplifier, wherein the threshold control circuit is responsive to the reset signal to remove a bias voltage which is present in at least one of the first and second amplified signals.

7. The optical receiving apparatus according to claim 6, wherein the fixed voltage level is higher than a reference voltage level of the first amplified signal.

8. The optical receiving apparatus according to claim 6, wherein the reset signal is a pulse signal having a given period, and the given period of the pulse signal is equal to an amount of time that the other of the data detection signals and the output of the delay circuit are simultaneously input into the logic circuit.

9. The optical receiving apparatus according to claim 6, wherein the delay circuit delays one of the first and second data detection signals for a given period, and wherein the given period is equal to or more than an amount of time needed by the second peak hold circuit to remove the bias voltage from the second amplified signal.

10. The optical receiving apparatus according to claim 6, wherein the threshold control circuit comprises:
a first peak hold circuit which outputs a first peak signal corresponding to a peak value of the first amplified signal; and
a second peak hold circuit which outputs a second peak signal corresponding to a peak value of the second amplified signal;
wherein the second peak hold circuit is responsive to the reset signal to remove the bias voltage from the second peak signal.

11. The optical receiving apparatus according to claim 10, wherein the threshold control circuit further comprises:
a first adder which adds the first amplified signal and the second peak signal;
a second adder which adds the second amplified signal and the first peak signal; and
a differential amplifier which differentially amplifies respective outputs from the first and second adders.

12. The optical receiving apparatus according to claim 11, further comprising a second comparator which discriminates an output of the differential amplifier with reference to a predetermined reference level, and outputs an output signal.

13. An optical receiving apparatus, comprising:
a light receiving element which converts an optical input signal into a corresponding electrical signal;
a pre-amplifier having an input which receives the electrical signal from the light receiving element, a non-inverting output which outputs a first amplified signal, and an inverting output which outputs a second amplified signal which is phase inverted relative to the first amplified signal;
a data detection circuit having a fixed voltage supply, a differentiation circuit, a first comparator and a latch circuit, wherein the fixed voltage supply supplies a fixed voltage to the first comparator, wherein the differentiation circuit differentiates the second amplified signal and outputs a differentiated signal, wherein the first comparator compares the first amplified signal with the fixed voltage, and wherein the latch circuit latches an output of the first comparator and outputs a first detection signal and a second detection signal which is phase inverted relative to the first detection signal;
a reset circuit which receives the first and second data detection signals from the data detection circuit, and which outputs a reset signal in response to the data detection circuit.
a threshold control circuit which detects and outputs first and second peak values of the respective first and second amplified signals output from the pre-amplifier, wherein the threshold control circuit receives the reset signal to remove a bias voltage of which is preset in at least one of the first and second amplified signals.

14. The optical receiving apparatus according to claim 13, wherein the reset circuit further comprises:
a delay circuit which delays one of the first and second detection signals; and
a logic circuit which multiplies the other of the first and second detection signals with an output of the delay circuit.

15. The optical receiving apparatus according to claim 13, wherein an initial voltage level of the differentiated signal is higher than the fixed voltage level.

16. The optical receiving apparatus according to claim 13, wherein the first comparator outputs an output signal while the differentiated signal level is below the fixed voltage level.

17. The optical receiving apparatus according to claim 13, wherein the delay circuit delays one of the first and second data detection signals for a given period, and wherein the given period is equal to or more than an amount of time needed by the second peak hold circuit to remove the bias voltage from the second amplified signal.

18. The optical receiving apparatus according to claim 13, wherein the threshold control circuit comprises:
a first peak hold circuit which outputs a first peak signal corresponding to a peak value of the first amplified signal; and
a second peak hold circuit which outputs a second peak signal corresponding to a peal value of the second amplified signal;
wherein the second peak hold circuit is responsive to the reset signal to remove the bias voltage from the second peak signal.

19. The optical receiving apparatus according to claim 18, wherein the threshold control circuit further comprises:
a first adder which adds the first amplified signal and the second peak signal;
a second adder which adds the second amplified signal and the first peak signal; and
a differential amplifier which differentially amplifies respective outputs from the first and second adders.

20. The optical receiving apparatus according to claim 19, further comprising a second comparator which discriminates an output of the differential amplifier with reference to a predetermined reference level, and outputs an output signal.
